(19) United States
(12) Patent Application Publication
(10) Pub. No.: US 2022/0087013 A1
(43) Pub. Date: Mar. 17, 2022

(54) TRANSMISSION PATH

(71) Applicant: SONY SEMICONDUCTOR SOLUTIONS CORPORATION, KANAGAWA (JP)

(72) Inventor: KENJI NONAKA, KANAGAWA (JP)

(21) Appl. No.: 17/299,916

(22) PCT Filed: Oct. 31, 2019
(86) PCT No.: PCT/JP2019/042809

§ 371 Date: Jun. 4, 2021

(30) Foreign Application Priority Data
Dec. 14, 2018 (JP) 2018-234846

(51) Int. Cl. H05K 1/02; G01S 13/32; H04B 10/50

(52) U.S. Cl. CPC H05K 1/0234; H04B 10/50; H05K 1/025; G01S 13/32

(57) ABSTRACT

An object of the present technique is to provide a transmission path that is capable of preventing deterioration of signal quality of a transmitted electric signal. The transmission path includes a reference portion, a first reflection suppressing portion, a second reflection suppressing portion, a first non-reference portion, and a second non-reference portion. The reference portion has an impedance that differs from each of the first non-reference portion and the second non-reference portion, and the first reflection suppressing portion has an impedance that is capable of suppressing a reflection coefficient of an impedance of the first transmission/reception terminal and an impedance of the first non-reference portion and has an electrical length that is equal to or shorter than an electrical length of the reference portion. The second reflection suppressing portion has an impedance that is capable of suppressing a reflection coefficient of an impedance of the second transmission/reception terminal and the impedance of the second non-reference portion and has an electrical length that is equal to or shorter than the electrical length of the reference portion.

### TECHNICAL FIELD

The present technique relates to a transmission path for transmitting a predetermined electric signal.

### BACKGROUND ART

An electric signal that is transmitted along a transmission path is reflected at a portion with a different impedance of the transmission path. When a reflected wave is created on the transmission path, signal quality of the electric signal that is transmitted along the transmission path deteriorates. Known methods of suppressing reflection of an electric signal that is created in a transmission path include providing a matching circuit using elements (components) such as an inductor, a resistor, and a capacitor (LRC), adjusting an electrical length of the transmission path, and using a stair-like stepped impedance between an impedance-unmatched portion and a transmission/reception terminal (for example, PTL 1).

### CITATION LIST

### Patent Literature

### [PTL 1]

### JP 2017-38133 A

### SUMMARY

### Technical Problem

While the method using LRC elements enables reflection characteristics of a characteristic band to be improved, reflection characteristics of other bands deteriorate. Therefore, the method using LRC elements has a problem in that the method is hardly adaptable to improving characteristics of signals having a wide-band frequency component such as a digital signal. In addition, the method using a stair-like stepped impedance between an impedance-unmatched portion and a transmission/reception terminal has a problem in that an effect of improving reflection characteristics is hardly produced in a case of a transmission path that includes a reference portion and non-reference portions on both sides of the reference portion.

An object of the present technique is to provide a transmission path that is capable of preventing deterioration of signal quality of a transmitted electric signal.

### Solution to Problem

In order to achieve the object described above, a transmission path according to an aspect of the present technique includes: a reference portion that is provided between a first transmission/reception terminal and a second transmission/reception terminal; a first region that is provided between one of both sides of the reference portion and the first transmission/reception terminal; a second region that is provided between the other of both sides of the reference portion and the second transmission/reception terminal; a first non-reference portion that is provided between the reference portion and the first region; and a second non-reference portion that is provided between the reference portion and the second region, wherein the reference portion has an impedance that differs from each of the first non-reference portion and the second non-reference portion, the first region has an impedance that is capable of suppressing a reflection coefficient of an impedance of the first transmission/reception terminal and an impedance of the first non-reference portion and has an electrical length that is equal to or shorter than an electrical length of the reference portion, and the second region has an impedance that is capable of suppressing a reflection coefficient of an impedance of the second transmission/reception terminal and an impedance of the second non-reference portion and has an electrical length that is equal to or shorter than the electrical length of the reference portion.

### BRIEF DESCRIPTION OF DRAWINGS

FIG. 1 is a diagram that schematically shows a general configuration and impedances of a transmission path according to an embodiment of the present technique.

FIG. 2 is a (first) diagram showing a simulation result of frequency characteristics of reflected waves created on a transmission path according to the embodiment of the present technique and a transmission path according to a comparative example.

FIG. 3 is a (second) diagram showing a simulation result of frequency characteristics of reflected waves created on a transmission path according to the embodiment of the present technique and a transmission path according to the comparative example.

FIG. 4 is a diagram that schematically shows a general configuration and impedances of a transmission path according to a modification of the embodiment of the present technique.

FIG. 5 is a diagram that schematically shows a general configuration and impedances of a transmission path according to a first example of the embodiment of the present technique.

FIG. 6 is a diagram that schematically shows a general configuration and impedances of a transmission path according to a second example of the embodiment of the present technique.

### DESCRIPTION OF EMBODIMENTS

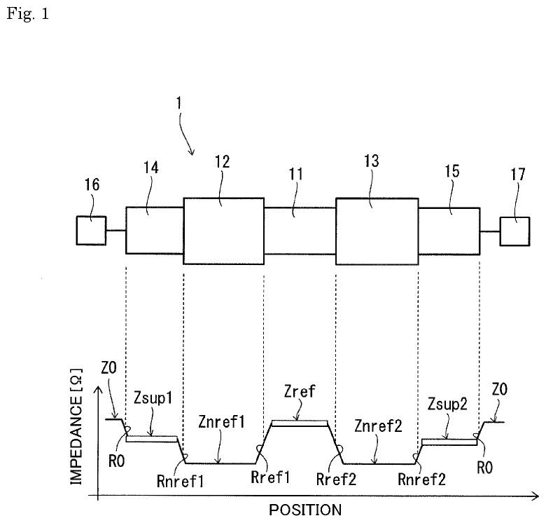

A transmission path according to an embodiment of the present technique will be described with reference to FIGS. 1 to 6. First, a general configuration of the transmission path according to the present embodiment will be described with reference to FIG. 1. An upper half of FIG. 1 schematically shows a general configuration of a transmission path 1 according to the present embodiment and a lower half of FIG. 1 schematically shows impedances of the transmission path 1. An abscissa of a diagram shown in the lower half of FIG. 1 represents a position of the transmission path 1 and an ordinate of the diagram represents a value [Q] of an impedance of the transmission path 1.

As shown in the upper half of FIG. 1, the transmission path 1 according to the present embodiment includes a reference portion 11 that is provided between a first transmission/reception terminal 16 and a second transmission/reception terminal 17. The transmission path 1 includes a first reflection suppressing portion (an example of the first region) 14 that is provided between one of both sides of the reference portion 11 and the first transmission/reception terminal 16 and a second reflection suppressing portion (an example of the second region) 15 that is provided between the other of both sides of the reference portion 11 and the second transmission/reception terminal 17. The transmission path 1 includes a first non-reference portion 12 that is provided between the reference portion 11 and the first reflection suppressing portion 14 and a second non-reference portion 13 that is provided between the reference portion 11 and the second reflection suppressing portion 15.

The first reflection suppressing portion 14 has a rectangular shape. In addition, the first reflection suppressing portion 14 may have tapered corners. Specifically, the first reflection suppressing portion 14 may have a shape in which a corner on a side of the first transmission/reception terminal 16 is chamfered and a corner on a side of the first non-reference portion 12 is inclined outward. The second reflection suppressing portion 15 has a rectangular shape. In addition, the second reflection suppressing portion 15 may have tapered corners. Specifically, the second reflection suppressing portion 15 may have a shape in which a corner on a side of the second transmission/reception terminal 17 is chamfered and a corner on a side of the second non-reference portion 13 is inclined outward.

As shown in the lower half of FIG. 1, the reference portion 11 has an impedance that differs from each of the first non-reference portion 12 and the second non-reference portion 13. More specifically, the reference portion 11 has an impedance Zref that is a larger value than an impedance Znref1 of the first non-reference portion 12. The reference portion 11 has the impedance Zref that is a larger value than an impedance Znref2 of the second non-reference portion 13.

In addition, the first reflection suppressing portion 14 has an impedance Zsup1 that is capable of suppressing a reflection coefficient of an impedance Z0 of the first transmission/reception terminal 16 and the impedance Znref1 of the first non-reference portion 12 and has an electrical length EL1 that is equal to or shorter than an electrical length ELref of the reference portion 11. The second reflection suppressing portion 15 has an impedance Zsup2 that is capable of suppressing a reflection coefficient of an impedance Z0 of the second transmission/reception terminal 17 and the impedance Znref2 of the second non-reference portion 13 and has an electrical length EL2 that is equal to or shorter than the electrical length ELref of the reference portion 11.

As shown in FIG. 1, the reference portion 11 has the impedance Zref that is higher than the respective impedances Znref1 and Znref2 of the first non-reference portion 12 and the second non-reference portion 13. Hereinafter, the respective reference signs “Zref, Znref1, and Znref2” of the impedances will also be used as values of the impedances. The respective impedances of the reference portion 11, the first non-reference portion 12, and the second non-reference portion 13 satisfy a relationship expressed by Expression (1) below.

Zref>Znref1 and Zref>Znref2 (1)

Although the impedance Znref of the first non-reference portion 12 and the impedance Znref2 of the second non-reference portion 13 need not be the same value, both impedances must be values that are smaller than the value of the impedance Zref of the reference portion 11.

The first reflection suppressing portion 14 has the impedance Zsup1 that suppresses the reflection coefficient of the impedance Z0 of the first transmission/reception terminal 16 and the impedance Znref1 of the first non-reference portion 12 to ¼ to ½. Hereinafter, the reference sign “Z0” of the impedances of the first transmission/reception terminal 16 and the second transmission/reception terminal 17 will also be used as values of the impedances. The impedance Zsup1 of the first reflection suppressing portion 14 satisfies a relationship expressed by Expression (2) below.

Zsup1=√(Z0×Znref1) (2)

The second reflection suppressing portion 15 has the impedance Zsup2 that suppresses the reflection coefficient of the impedance Z0 of the second transmission/reception terminal 17 and the impedance Znref2 of the second non-reference portion 13 to ¼ to ½. For example, the impedance Zsup2 of the second reflection suppressing portion 15 satisfies a relationship expressed by Expression (3) below.

Zsup2=√(Z0×Znref2) (3)

The first reflection suppressing portion 14 has the electrical length EL1 that is ½ to 1/1 of the electrical length ELref of the reference portion 11. In other words, the first reflection suppressing portion 14 has the electrical length EL1 that ranges from a length that is half of the electrical length ELref of the reference portion 11 to a same length as the electrical length ELref. Hereinafter, the reference signs “ELref and EL1” of the electrical lengths will also be used as values of the electrical lengths. The electrical length EL1 of the first reflection suppressing portion 14 satisfies a relationship expressed by Expression (4) below.

ELref/2<EL1≤ELref (4)

The second reflection suppressing portion 15 has the electrical length EL2 that is ½ to 1/1 of the electrical length ELref of the reference portion 11. In other words, the second reflection suppressing portion 15 has the electrical length EL2 that ranges from a length that is half of the electrical length ELref of the reference portion 11 to a same length as the electrical length ELref. Hereinafter, by also using the reference sign “EL2” of the electrical length as a value of the electrical length, the electrical length EL2 of the second reflection suppressing portion 15 satisfies a relationship expressed by Expression (5) below.

ELref/2<EL2≤ELref (5)

Let us assume that the first reflection suppressing portion 14 has the impedance Zsup1 that is incapable of suppressing the reflection coefficient of the impedance Z0 of the first transmission/reception terminal 16 and the impedance Znref1 of the first non-reference portion 12 to within a range of ¼ to ½. In addition, let us assume that the second reflection suppressing portion 15 has the impedance Zsup2 that is incapable of suppressing the reflection coefficient of the impedance Z0 of the second transmission/reception terminal 17 and the impedance Znref2 of the second non-reference portion 13 to within a range of ¼ to ½. Furthermore, let us assume that the first reflection suppressing portion 14 has the electrical length EL1 that is ½ to 1/1 of the electrical length ELref of the reference portion 11. In addition, let us assume that the second reflection suppressing portion 15 has the electrical length EL2 that is ½ to 1/1 of the electrical length ELref of the reference portion 11. When the transmission path 1 is formed so as satisfy even at least one of these conditions, reflection characteristics of a transmission path 5 deteriorate due to complex elements created by reflection surfaces R0, Rref1, Rref2, Rnref1, and Rnref2 (details to be provided later).

The impedances Zsup1 and Zsup2 and the electrical lengths EL1 and EL2 of the first reflection suppressing portion 14 and the second reflection suppressing portion 15 can be realized by adjusting a wiring width, a dielectric constant of a wiring material, a height (thickness) of a wiring, a height (thickness) of a resist (even when a resist is absent), and the like.

Next, an operation of the transmission path 1 will be described. For example, an electric signal (a digital signal or an analog signal) that is transmitted from the first transmission/reception terminal 16 to the transmission path 1 is reflected by and transmitted through a reflection surface R0 that is formed in a connecting portion between the first transmission/reception terminal 16 and the first reflection suppressing portion 14. The electric signal having been transmitted through the reflection surface R0 is transmitted along the first reflection suppressing portion 14 and is reflected by and transmitted through a reflection surface Rnref1 that is formed in a connecting portion between the first reflection suppressing portion 14 and the first non-reference portion 12. The electric signal having been transmitted through the reflection surface Rnref1 is transmitted along the first non-reference portion 12 and is reflected by and transmitted through a reflection surface Rref1 that is formed in a connecting portion between the first non-reference portion 12 and the reference portion 11. The electric signal having been transmitted through the reflection surface Rref1 is transmitted along the reference portion 11 and is reflected by and transmitted through a reflection surface Rref2 that is formed in a connecting portion between the reference portion 11 and the second non-reference portion 13. The electric signal having been transmitted through the reflection surface Rref2 is transmitted along the second non-reference portion 13 and is reflected by and transmitted through a reflection surface Rnref2 that is formed in a connecting portion between the second non-reference portion 13 and the second reflection suppressing portion 15. The electric signal having been transmitted through the reflection surface Rnref2 is transmitted along the second reflection suppressing portion 15, reflected by and transmitted through a reflection surface R0 that is formed in a connecting portion between the second reflection suppressing portion 15 and the second transmission/reception terminal 17, and sent to the outside from the second transmission/reception terminal 17.

As described above, when a reflected wave Wref1 that is reflected by the reflection surface Rref1 and a reflected wave Wref2 that is reflected by the reflection surface Rref2 overlap with each other as an electric signal is transmitted along the transmission path 1, a reflected wave Wref with a large amplitude is created and causes signal quality to deteriorate. The amplitude of the reflected wave Wref is maximized when a wavelength λ of the reflected wave Wref equals λ/4 of the electrical length ELref of the reference portion 11.

The first reflection suppressing portion 14 has the impedance Zsup1 that is capable of suppressing the reflection coefficient of the impedance Z0 of the first transmission/reception terminal 16 and the impedance Znref1 of the first non-reference portion 12 to ¼ to ½ and has the electrical length EL1 that is equal to or shorter than the electrical length ELref of the reference portion 11. Therefore, a reflected wave WO that is reflected by the reflection surface R0 based on the first transmission/reception terminal 16 and a reflected wave Wnref1 that is reflected by the reflection surface Rnref1 have a phase having been reversed by 180 degrees from the reflected wave Wref and an amplitude that is ¼ to ½ of an amplitude of the reflected wave Wref. In addition, the second reflection suppressing portion 15 has the impedance Zsup2 that is capable of suppressing the reflection coefficient of the impedance Z0 of the second transmission/reception terminal 17 and the impedance Znref2 of the second non-reference portion 13 to ¼ to ½ and has the electrical length EL2 that is equal to or shorter than the electrical length ELref of the reference portion 11. Therefore, a reflected wave WO that is reflected by the reflection surface R0 based on the second transmission/reception terminal 17 and a reflected wave Wnref2 that is reflected by the reflection surface Rnref2 have a phase having been reversed by 180 degrees from the reflected wave Wref and an amplitude that is ¼ to ½ of the amplitude of the reflected wave Wref.

Therefore, the reflected wave Wnref1 and the reflected wave Wnref2 cancel a frequency that maximizes an amplitude of the reflected wave Wref. Accordingly, reflected waves created on the transmission path 1 can be reduced and deterioration of signal quality of an electric signal that is transmitted along the transmission path 1 can be prevented.

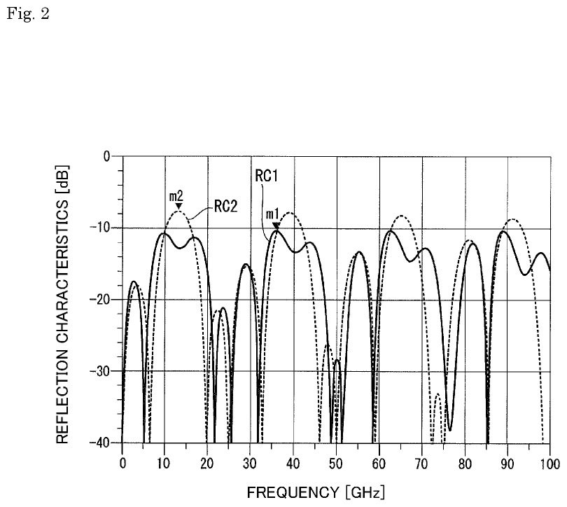

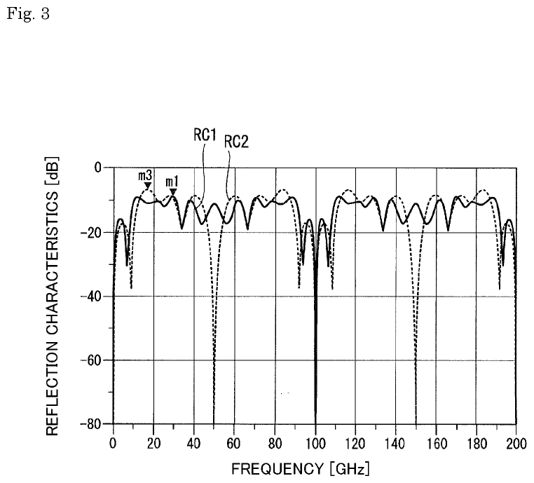

Next, an advantageous effect of the transmission path 1 according to the present embodiment will be described using FIGS. 2 and 3 with reference to FIG. 1. FIG. 2 is a diagram showing a simulation result of frequency characteristics of a reflected wave in a case where respective impedances of the reference portion 11, the first non-reference portion 12, and the second non-reference portion 13 satisfy the relationship expressed by Expression (1) and the impedance Znref1 of the first non-reference portion 12 and the impedance Znref2 of the second non-reference portion 13 are equal to each other. FIG. 3 is a diagram showing a simulation result of frequency characteristics of a reflected wave in a case where respective impedances of the reference portion 11, the first non-reference portion 12, and the second non-reference portion 13 satisfy the relationship expressed by Expression (1) and the impedance Zref of the reference portion 11 is lower than the impedance Znref1 of the first non-reference portion 12 and the impedance Znref1 of the first non-reference portion 12 is lower than the impedance Znref2 of the second non-reference portion 13. An abscissa of the graphs shown in FIGS. 2 and 3 represent frequency [GHz] and an ordinate of the graphs represent reflection characteristics [dB]. A characteristic RC1 depicted by a solid line in FIGS. 2 and 3 represents frequency characteristics of a reflected wave created in the transmission path 1 and a characteristic RC2 depicted by a dashed line in FIGS. 2 and 3 represents frequency characteristics of a reflected wave created in a transmission path that does not include the first reflection suppressing portion 14 and the second reflection suppressing portion 15 (a transmission path according to a comparative example).

As indicated by the characteristics RC1 and a black triangle m1 in FIG. 2, the reflected wave created in the transmission path 1 according to the present embodiment reaches a maximum level of −10.390 dB at a frequency of 36.13 GHz. On the other hand, as indicated by the characteristics RC2 and a black triangle m2 in FIG. 2, the reflected wave created in the transmission path according to the comparative example reaches a maximum level of −7.579 dB at a frequency of 13.01 GHz. In this manner, the transmission path 1 is capable of suppressing a level of a reflected wave.

In addition, as shown in FIG. 2, the reflected wave created in the transmission path 1 has frequency characteristics having a concave shape in a vicinity of a frequency at which the level of the reflected wave created in the transmission path according to the comparative example peaks (for example, the black triangle m2). Therefore, by including the first reflection suppressing portion 14 and the second reflection suppressing portion 15, the transmission path 1 is capable of suppressing a peak level of a reflected wave that is created when the first reflection suppressing portion 14 and the second reflection suppressing portion 15 are not included.

As indicated by the characteristics RC1 and the black triangle m1 in FIG. 3, the reflected wave created in the transmission path 1 according to the present embodiment reaches a maximum level of −9.049 dB at a frequency of 29.14 GHz. On the other hand, as indicated by the characteristics RC2 and a black triangle m3 in FIG. 3, the reflected wave created in the transmission path according to the comparative example reaches a maximum level of −6.640 dB at a frequency of 16.48 GHz. In this manner, the transmission path 1 is capable of suppressing a level of a reflected wave.

In addition, as shown in FIG. 3, the reflected wave created in the transmission path 1 has frequency characteristics having a concave shape in a vicinity of a frequency at which the level of the reflected wave created in the transmission path according to the comparative example peaks (for example, the black triangle m3). Therefore, by including the first reflection suppressing portion 14 and the second reflection suppressing portion 15, the transmission path 1 is capable of suppressing a peak level of a reflected wave that is created when the first reflection suppressing portion 14 and the second reflection suppressing portion 15 are not included.

As described above, the transmission path 1 according to the present embodiment includes: the reference portion 11 that is provided between the first transmission/reception terminal 16 and the second transmission/reception terminal 17; the first reflection suppressing portion 14 that is provided between one of both sides of the reference portion 11 and the first transmission/reception terminal 16; the second reflection suppressing portion 15 that is provided between the other of both sides of the reference portion 11 and the second transmission/reception terminal 17; the first non-reference portion 12 that is provided between the reference portion 11 and the first reflection suppressing portion 14; and the second non-reference portion 13 that is provided between the reference portion 11 and the second reflection suppressing portion 15. The reference portion 11 has an impedance that differs from each of the first non-reference portion 12 and the second non-reference portion 13, and the first reflection suppressing portion 14 has an impedance that is capable of suppressing a reflection coefficient of an impedance of the first transmission/reception terminal 16 and an impedance of the first non-reference portion 12 and has an electrical length that is equal to or shorter than an electrical length of the reference portion 11. The second reflection suppressing portion 15 has an impedance that is capable of suppressing a reflection coefficient of an impedance of the second transmission/reception terminal 17 and an impedance of the second non-reference portion 13 and has an electrical length that is equal to or shorter than the electrical length of the reference portion 11.

The transmission path 1 configured as described above is capable of suppressing a reflection of an electric signal even when having portions with different impedances. Therefore, the transmission path 1 is capable of preventing deterioration of signal quality of a transmitted electric signal.

(Modification)

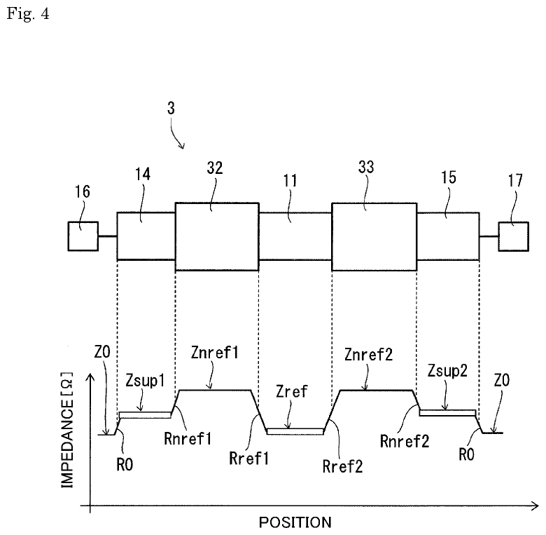

Next, a transmission path according to a modification of the present embodiment will be described with reference to FIG. 4. An upper half of FIG. 4 schematically shows a general configuration of a transmission path 3 according to the present modification and a lower half of FIG. 4 schematically shows impedances of the transmission path 3. An abscissa of a diagram shown in the lower half of FIG. 3 represents a position of the transmission path 3 and an ordinate of the diagram represents a value [Q] of an impedance of the transmission path 3. With respect to the transmission path 3, components that perform a similar action or function to that of the transmission path 1 according to the embodiment described above will be assigned a same reference sign and a description thereof will be omitted. A feature of the transmission path 3 according to the present modification is that a reference portion has a lower impedance than a first non-reference portion and a second non-reference portion.

As shown in the upper half of FIG. 4, the transmission path 3 according to the present modification includes a first non-reference portion 32 that is provided between the reference portion 11 and the first reflection suppressing portion 14 and a second non-reference portion 33 that is provided between the reference portion 11 and the second reflection suppressing portion 15.

As shown in the lower half of FIG. 4, the reference portion 11 has an impedance that differs from each of the first non-reference portion 32 and the second non-reference portion 33. More specifically, the reference portion 11 has the impedance Zref that is a smaller value than an impedance Znref1 of the first non-reference portion 32. The reference portion 11 has the impedance Zref that is a larger value than an impedance Znref2 of the second non-reference portion 33.

In addition, the first reflection suppressing portion 14 has the impedance Zsup1 that is capable of suppressing a reflection coefficient of the impedance Z0 of the first transmission/reception terminal 16 and the impedance Znref1 of the first non-reference portion 32 and has the electrical length EL1 that is equal to or shorter than the electrical length ELref of the reference portion 11. The second reflection suppressing portion 15 has the impedance Zsup2 that is capable of suppressing a reflection coefficient of the impedance Z0 of the second transmission/reception terminal 17 and the impedance Znref2 of the second non-reference portion 33 and has the electrical length EL2 that is equal to or shorter than the electrical length ELref of the reference portion 11.

As shown in FIG. 4, the reference portion 11 has the impedance Zref that is lower than the respective impedances Znref1 and Znref2 of the first non-reference portion 32 and the second non-reference portion 33. In the present modification, the respective impedances of the reference portion 11, the first non-reference portion 32, and the second non-reference portion 33 satisfy a relationship expressed by Expression (6) below.

Zref<Znref1 and Zref<Znref2 (6)

Although the impedance Znref of the first non-reference portion 32 and the impedance Znref2 of the second non-reference portion 33 need not be the same value, both impedances must be values that are larger than the value of the impedance Zref of the reference portion 11.

Next, an operation of the transmission path 3 will be briefly described. As shown in FIG. 4, when the reference portion 11 has the impedance Zref that is lower than the impedance Znref1 of the first non-reference portion 32, a reflection surface Rref1 is formed in a connecting portion between the reference portion 11 and the first non-reference portion 32. In a similar manner, when the reference portion 11 has the impedance Zref that is lower than the impedance Znref2 of the second non-reference portion 33, a reflection surface Rref2 is formed in a connecting portion between the reference portion 11 and the second non-reference portion 33. Therefore, an electric signal (a digital signal or an analog signal) transmitted along the transmission path 3 is reflected by the reflection surfaces Rref1 and Rref2. Accordingly, a reflected wave Wref with a large amplitude is created on the transmission path 3.

However, the transmission path 3 includes the first reflection suppressing portion 14 and the second reflection suppressing portion 15. Therefore, the first reflection suppressing portion 14 has the impedance Zsup1 that is capable of suppressing the reflection coefficient of the impedance Z0 of the first transmission/reception terminal 16 and the impedance Znref1 of the first non-reference portion 32 to ¼ to ½ and has the electrical length EL1 that is equal to or shorter than the electrical length ELref of the reference portion 11. Therefore, a reflected wave WO that is reflected by the reflection surface R0 based on the first transmission/reception terminal 16 and a reflected wave Wnref1 that is reflected by the reflection surface Rnref1 have a phase having been reversed by 180 degrees from the reflected wave Wref and an amplitude that is ¼ to ½ of an amplitude of the reflected wave Wref. In addition, the second reflection suppressing portion 15 has the impedance Zsup2 that is capable of suppressing the reflection coefficient of the impedance Z0 of the second transmission/reception terminal 17 and the impedance Znref2 of the second non-reference portion 33 to ¼ to ½ and has the electrical length EL2 that is equal to or shorter than the electrical length ELref of the reference portion 11. Therefore, a reflected wave WO that is reflected by the reflection surface R0 based on the second transmission/reception terminal 17 and a reflected wave Wnref2 that is reflected by the reflection surface Rnref2 have a phase having been reversed by 180 degrees from the reflected wave Wref and an amplitude that is ¼ to ½ of the amplitude of the reflected wave Wref.

Therefore, the reflected wave Wnref1 and the reflected wave Wnref2 cancel a frequency that maximizes an amplitude of the reflected wave Wref. Accordingly, reflected waves created on the transmission path 3 can be reduced and deterioration of signal quality of an electric signal that is transmitted along the transmission path 3 can be prevented.

As described above, the transmission path 3 according to the present modification produces an advantageous effect similar to that of the transmission path 1 according to the embodiment described above.

### First Example

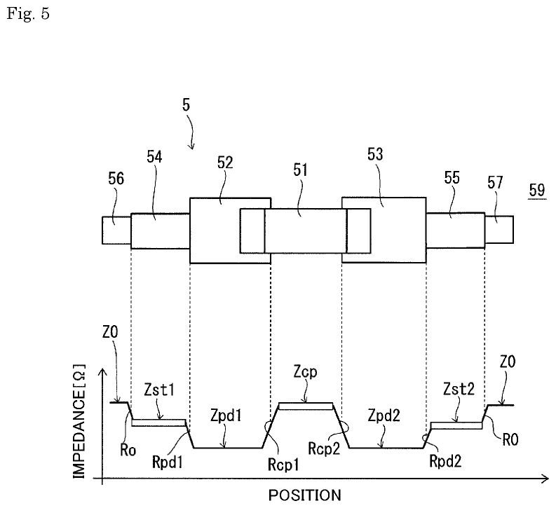

Next, a transmission path according to a first example of the present embodiment will be described with reference to FIG. 5. An upper half of FIG. 5 schematically shows a general configuration of a transmission path 5 according to the present example and a lower half of FIG. 5 schematically shows impedances of the transmission path 5. An abscissa of a diagram shown in the lower half of FIG. 5 represents a position of the transmission path 5 and an ordinate of the diagram represents a value [Ω] of an impedance of the transmission path 5.

As shown in the upper half of FIG. 5, the transmission path 5 according to the present example includes a chip component (an example of the reference portion) 51 that is provided between a first transmission/reception terminal 56 and a second transmission/reception terminal 57. The chip component 51 is provided on a substrate 59. The transmission path 5 includes a first wiring portion (an example of the first region) 54 that is provided between one of both sides of the chip component 51 and the first transmission/reception terminal 56 and a second wiring portion (an example of the second region) 55 that is provided between the other of both sides of the chip component 51 and the second transmission/reception terminal 57. The first wiring portion 54 and the second wiring portion 55 are formed in the substrate 59. The transmission path 5 includes a first component pad (an example of the first non-reference portion) 52 that is provided between the chip component 51 and the first wiring portion 54 and a second component pad (an example of the second non-reference portion) 53 that is provided between the chip component 51 and the second wiring portion 55. The chip component 51 is, for example, soldered to the first component pad 52 and the second component pad 53. The first component pad 52 and the second component pad 53 are formed in the substrate 59 in order to mount the chip component 51 to the substrate 59. As described above, in the present example, the reference portion is the chip component provided on the substrate, the first non-reference portion and the second non-reference portion are the component pads for providing the chip component on the substrate, and the first reflection suppressing portion (an example of the first region) and the second reflection suppressing portion (an example of the second region) are the wiring portions formed in the substrate.

The first wiring portion 54 has a rectangular shape. In addition, the first wiring portion 54 may have tapered corners. Specifically, the first wiring portion 54 may have a shape in which a corner on a side of the first transmission/reception terminal 56 is chamfered and a corner on a side of the first component pad 52 is inclined outward. The second wiring portion 55 has a rectangular shape. In addition, the second wiring portion 55 may have tapered corners. Specifically, the second wiring portion 55 may have a shape in which a corner on a side of the second transmission/reception terminal 57 is chamfered and a corner on a side of the second component pad 53 is inclined outward.

As shown in the lower half of FIG. 5, the chip component 51 has an impedance that differs from each of the first component pad 52 and the second component pad 53. More specifically, the chip component 51 has an impedance Zcp that is a larger value than an impedance Zpd1 of the first component pad 52. The chip component 51 has the impedance Zcp that is a larger value than an impedance Zpd2 of the second component pad 53.

In addition, the first wiring portion 54 has an impedance Zst1 that is capable of suppressing a reflection coefficient of an impedance Z0 of the first transmission/reception terminal 56 and the impedance Zpd1 of the first component pad 52 and has an electrical length ELt1 that is equal to or shorter than an electrical length ELcp of the chip component 51. The impedance Zpd1 of the first component pad 52 includes an impedance of solder (not illustrated) that is used to solder the chip component 51 to the first component pad 52. The second wiring portion 55 has an impedance Zst2 that is capable of suppressing a reflection coefficient of an impedance Z0 of the second transmission/reception terminal 57 and the impedance Zpd2 of the second component pad 53 and has an electrical length ELt2 that is equal to or shorter than the electrical length ELcp of the chip component 51. The impedance Zpd2 of the second component pad 53 includes an impedance of solder (not illustrated) that is used to solder the chip component 51 to the second component pad 53.

As shown in FIG. 5, the chip component 51 has the impedance Zcp that is higher than the respective impedances Zpd1 and Zpd2 of the first component pad 52 and the second component pad 53. Hereinafter, the respective reference signs “Zcp, Zpd1, and Zpd2” of the impedances will also be used as values of the impedances. The respective impedances of the chip component 51, the first component pad 52, and the second component pad 53 satisfy a relationship expressed by Expression (7) below.

Zcp>Zpd1 and Zcp>Zpd2 (7)

Although the impedance Zpd1 of the first component pad 52 and the impedance Zpd2 of the second component pad 53 need not be the same value, both impedances must be values that are smaller than the value of the impedance Zcp of the chip component 51.

The first wiring portion 54 has the impedance Zst1 that suppresses the reflection coefficient of the impedance Z0 of the first transmission/reception terminal 56 and the impedance Zpd1 of the first component pad 52 to ¼ to ½. Hereinafter, the reference sign “Z0” of the impedances of the first transmission/reception terminal 56 and the second transmission/reception terminal 57 will also be used as values of the impedances. The impedance Zst1 of the first wiring portion 54 satisfies a relationship expressed by Expression (8) below.

Zst1=√(Z0×Zpd1) (8)

The second wiring portion 55 has the impedance Zst2 that suppresses the reflection coefficient of the impedance Z0 of the second transmission/reception terminal 57 and the impedance Zpd2 of the second component pad 53 to ¼ to ½. For example, the impedance Zst2 of the second wiring portion 55 satisfies a relationship expressed by Expression (9) below.

Zst2=√(Z0×Zpd2) (9)

The first wiring portion 54 has the electrical length ELt1 that is ½ to 1/1 of the electrical length ELcp of the chip component 51. In other words, the first wiring portion 54 has the electrical length ELt1 that ranges from a length that is half of the electrical length ELcp of the chip component 51 to a same length as the electrical length ELcp. Hereinafter, by also using the reference signs “ELcp and ELt1” of the electrical lengths as values of the electrical lengths, the electrical length ELt1 of the first wiring portion 54 satisfies a relationship expressed by Expression (10) below.

ELcp/2<ELt1≤ELcp (10)

The second wiring portion 55 has the electrical length ELt2 that is ½ to 1/1 of the electrical length ELcp of the chip component 51. In other words, the second wiring portion 55 has the electrical length ELt2 that ranges from a length that is half of the electrical length ELcp of the chip component 51 to a same length as the electrical length ELcp. Hereinafter, the reference sign “EL2” of the electrical length will also be used as a value of the electrical length. The electrical length EL2 of the second wiring portion 55 satisfies a relationship expressed by Expression (11) below.

ELcp/2<ELt2≤ELcp (11)

Let us assume that the first wiring portion 54 has the impedance Zst1 that is incapable of suppressing the reflection coefficient of the impedance Z0 of the first transmission/reception terminal 56 and the impedance Zpd1 of the first component pad 52 to within a range of ¼ to ½. In addition, let us assume that the second wiring portion 55 has the impedance Zst2 that is incapable of suppressing the reflection coefficient of the impedance Z0 of the second transmission/reception terminal 57 and the impedance Zpd2 of the second component pad 53 to within a range of ¼ to ½. Furthermore, let us assume that the first wiring portion 54 has the electrical length ELt1 that is outside of a range from ½ to 1/1 of the electrical length ELcp of the chip component 51. In addition, let us assume that the second wiring portion 55 has the electrical length ELt2 that is outside of a range from ½ to 1/1 of the electrical length ELcp of the chip component 51. When the transmission path 5 is formed so as satisfy even at least one of these conditions, reflection characteristics of the transmission path 5 deteriorate due to complex elements created by two reflection surfaces R0 (details to be provided later) and reflection surfaces Rpd1, Rpd2, Rcp1, and Rcpt (details to be provided later).

The impedances Zst1 and Zst2 and the electrical lengths ELt1 and ELt2 of the first wiring portion 54 and the second wiring portion 55 can be realized by adjusting a wiring width, a dielectric constant of a wiring material, a height (thickness) of a wiring, and the like. In addition, the impedances Zst1 and Zst2 and the electrical lengths ELt1 and ELt2 of the first wiring portion 54 and the second wiring portion 55 can be realized depending on whether or not the first wiring portion 54 and the second wiring portion 55 are to be covered by a resist or by adjusting a height (thickness) of the resist.

Next, an operation of the transmission path 5 will be described. For example, an electric signal (a digital signal or an analog signal) that is transmitted from the first transmission/reception terminal 56 to the transmission path 5 is reflected by and transmitted through a reflection surface R0 that is formed in a connecting portion between the first transmission/reception terminal 56 and the first wiring portion 54. The electric signal having been transmitted through the reflection surface R0 is transmitted along the first wiring portion 54 and is reflected by and transmitted through a reflection surface Rpd1 that is formed in a connecting portion between the first wiring portion 54 and the first component pad 52. The electric signal having been transmitted through the reflection surface Rpd1 is transmitted along the first component pad 52 and is reflected by and transmitted through a reflection surface Rcp1 that is formed in a connecting portion between the first component pad 52 and the chip component 51. The electric signal having been transmitted through the reflection surface Rpd1 is transmitted along the chip component 51 and is reflected by and transmitted through a reflection surface Rcpt that is formed in a connecting portion between the chip component 51 and the second component pad 53. The electric signal having been transmitted through a reflection surface Rpd2 is transmitted along the second component pad 53 and is reflected by and transmitted through the reflection surface Rpd2 that is formed in a connecting portion between the second component pad 53 and the second wiring portion 55. The electric signal having been transmitted through the reflection surface Rpd2 is transmitted along the second wiring portion 55, reflected by and transmitted through a reflection surface R0 that is formed in a connecting portion between the second wiring portion 55 and the second transmission/reception terminal 57, and sent to the outside from the second transmission/reception terminal 57.

As described above, when a reflected wave Wcp1 that is reflected by the reflection surface Rcp1 and a reflected wave Wcp2 that is reflected by the reflection surface Rcpt overlap with each other as an electric signal is transmitted along the transmission path 5, a reflected wave Wcp with a large amplitude is created and causes signal quality to deteriorate. The amplitude of the reflected wave Wcp is maximized when a wavelength λ of the reflected wave Wcp equals λ/4 of the electrical length ELcp of the chip component 51.

The first wiring portion 54 has the impedance Zst1 that is capable of suppressing a reflection coefficient of the impedance Z0 of the first transmission/reception terminal 56 and the impedance Zpd1 of the first component pad 52 to ¼ to ½ and has the electrical length ELt1 that is equal to or shorter than the electrical length ELcp of the chip component 51. Therefore, a reflected wave WO that is reflected by the reflection surface R0 based on the first transmission/reception terminal 56 and a reflected wave Wpd1 that is reflected by the reflection surface Rpd1 have a phase having been reversed by 180 degrees from the reflected wave Wcp and an amplitude that is ¼ to ½ of an amplitude of the reflected wave Wcp. In addition, the second wiring portion 55 has the impedance Zst2 that is capable of suppressing a reflection coefficient of the impedance Z0 of the second transmission/reception terminal 57 and the impedance Zpd2 of the second component pad 53 to ¼ to ½ and has the electrical length ELt2 that is equal to or shorter than the electrical length ELcp of the chip component 51. Therefore, a reflected wave WO that is reflected by the reflection surface R0 based on the second transmission/reception terminal 57 and a reflected wave Wpd2 that is reflected by the reflection surface Rpd2 have a phase having been reversed by 180 degrees from the reflected wave Wcp and an amplitude that is ¼ to ½ of the amplitude of the reflected wave Wcp.

Therefore, the reflected wave Wpd1 and the reflected wave Wpd2 cancel a frequency that maximizes an amplitude of the reflected wave Wcp. Accordingly, reflected waves created on the transmission path 5 can be reduced and deterioration of quality of an electric signal that is transmitted along the transmission path 5 can be prevented.

As described above, the transmission path 5 according to the present example produces an advantageous effect similar to that of the transmission path 1 according to the embodiment described above. In addition, the transmission path 5 according to the present example enables deterioration of quality of a transmitted electric signal to be prevented without using special components by adjusting an impedance of the first wiring portion 54 that connects the first transmission/reception terminal 56 and the first component pad 52 to each other and an impedance of the second wiring portion 55 that connects the second transmission/reception terminal 57 and the second component pad 53 to each other.

In the transmission path 5 according to the present example, the chip component 51 has the impedance Zcp that is higher than the respective impedances Zpd1 and Zpd2 of the first component pad 52 and the second component pad 53. However, the chip component 51 may have the impedance Zcp that is lower than the respective impedances Zpd1 and Zpd2 of the first component pad 52 and the second component pad 53 and may satisfy a relationship expressed by Expression (12) below.

Ztp<Zpd1 and Ztp<Zpd2 (12)

### Second Example

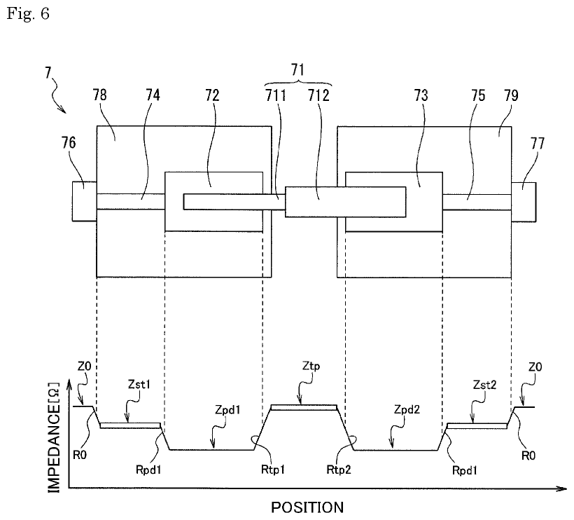

Next, a transmission path according to a second example of the present embodiment will be described with reference to FIG. 6. An upper half of FIG. 6 schematically shows a general configuration of a transmission path 7 according to the present example and a lower half of FIG. 6 schematically shows impedances of the transmission path 7. An abscissa of a diagram shown in the lower half of FIG. 6 represents a position of the transmission path 7 and an ordinate of the diagram represents a value [Ω] of an impedance of the transmission path 7.

As shown in the upper half of FIG. 6, the transmission path 7 according to the present example includes a terminal component (an example of the reference portion) 71 that is provided between a first transmission/reception terminal 76 and a second transmission/reception terminal 77. The terminal component 71 is an edge connector provided at respective ends of a substrate 78 and a substrate 79 for connecting the substrate 78 and the substrate 79. The terminal component 71 has a first component 711 provided on a side of the substrate 78 and a second component 712 provided on a side of the substrate 79. By inserting the first component 711 into the second component 712, the terminal component 71 can connect the substrate 78 and the substrate 79 to each other. An impedance Ztp of the terminal component 71 is an impedance in a state where the first component 711 is inserted into the second component 712. The first component 711 and the second component 712 that constitute the terminal component 71 have mutually different effective dielectric constants due to a difference in shapes or the like of dielectric bodies that form parts of the first component 711 and the second component 712. For example, the second component 712 has a lower effective dielectric constant than the first component 711. Therefore, while the first component 711 and the second component 712 have mutually different conductor shapes, the first component 711 and the second component 712 have a same characteristic impedance. Accordingly, a reflection surface is not formed in a connecting portion of the first component 711 and the second component 712 and the terminal component 71 has the impedance Ztp of which a value is constant through the first component 711 and the second component 712.

The transmission path 7 includes a first wiring portion (an example of the first region) 74 that is provided between one of both sides of the terminal component 71 and the first transmission/reception terminal 76 and a second wiring portion (an example of the second region) 75 that is provided between the other of both sides of the terminal component 71 and the second transmission/reception terminal 77. The transmission path 7 includes a first component pad (an example of the first non-reference portion) 72 that is provided between the terminal component 71 and the first wiring portion 74 and a second component pad (an example of the second non-reference portion) 73 that is provided between the terminal component 71 and the second wiring portion 75. The terminal component 71 is, for example, soldered to the first component pad 72 and the second component pad 73. As described above, in the present example, the reference portion is the terminal component provided on the substrate, the first non-reference portion and the second non-reference portion are the component pads for providing the terminal component on the substrate, and the first reflection suppressing portion (an example of the first region) and the second reflection suppressing portion (an example of the second region) are the wiring portions formed in the substrate.

The first wiring portion 74 has a rectangular shape. In addition, the first wiring portion 74 may have tapered corners. Specifically, the first wiring portion 74 may have a shape in which a corner on a side of the first transmission/reception terminal 76 is chamfered and a corner on a side of the first component pad 72 is inclined outward. The second wiring portion 75 has a rectangular shape. In addition, the second wiring portion 75 may have tapered corners. Specifically, the second wiring portion 75 may have a shape in which a corner on a side of the second transmission/reception terminal 77 is chamfered and a corner on a side of the second component pad 73 is inclined outward.

As shown in the lower half of FIG. 6, the terminal component 71 has an impedance that differs from each of the first component pad 72 and the second component pad 73. More specifically, the terminal component 71 has the impedance Ztp that is a larger value than an impedance Zpd1 of the first component pad 72. The terminal component 71 has the impedance Ztp that is a larger value than an impedance Zpd2 of the second component pad 73.

In addition, the first wiring portion 74 has an impedance Zst1 that is capable of suppressing a reflection coefficient of an impedance Z0 of the first transmission/reception terminal 76 and the impedance Zpd1 of the first component pad 72 and has an electrical length ELt1 that is equal to or shorter than an electrical length ELtp of the terminal component 71. The impedance Zpd1 of the first component pad 72 includes an impedance of solder (not illustrated) that is used to solder the terminal component 71 to the first component pad 72. The second wiring portion 75 has an impedance Zst2 that is capable of suppressing a reflection coefficient of an impedance Z0 of the second transmission/reception terminal 77 and the impedance Zpd2 of the second component pad 73 and has an electrical length ELt2 that is equal to or shorter than the electrical length ELtp of the terminal component 71. The impedance Zpd2 of the second component pad 73 includes an impedance of solder (not illustrated) that is used to solder the terminal component 71 to the second component pad 73.

As shown in FIG. 6, the terminal component 71 has the impedance Ztp that is higher than the respective impedances Zpd1 and Zpd2 of the first component pad 72 and the second component pad 73. Hereinafter, the respective reference signs “Ztp, Zpd1, and Zpd2” of the impedances will also be used as values of the impedances. The respective impedances of the terminal component 71, the first component pad 72, and the second component pad 73 satisfy a relationship expressed by Expression (13) below.

Ztp>Zpd1 and Ztp>Zpd2 (13)

Although the impedance Zpd1 of the first component pad 72 and the impedance Zpd2 of the second component pad 73 need not be the same value, both impedances must be values that are smaller than the value of the impedance Ztp of the terminal component 71.

The first wiring portion 74 has the impedance Zst1 that suppresses the reflection coefficient of the impedance Z0 of the first transmission/reception terminal 76 and the impedance Zpd1 of the first component pad 72 to ¼ to ½. Hereinafter, the reference sign “Z0” of the impedances of the first transmission/reception terminal 76 and the second transmission/reception terminal 77 will also be used as values of the impedances. The impedance Zst1 of the first wiring portion 74 satisfies the relationship expressed by Expression (8) above.

The second wiring portion 75 has the impedance Zst2 that suppresses the reflection coefficient of the impedance Z0 of the second transmission/reception terminal 77 and the impedance Zpd2 of the second component pad 73 to ¼ to ½. The impedance Zst2 of the second wiring portion 75 satisfies the relationship expressed by Expression (9) above.

The first wiring portion 74 has the electrical length ELt1 that is ½ to 1/1 of the electrical length ELtp of the terminal component 71. In other words, the first wiring portion 74 has the electrical length ELt1 that ranges from a length that is half of the electrical length ELtp of the terminal component 71 to a same length as the electrical length ELtp. Hereinafter, the reference signs “ELtp and ELt1” of the electrical lengths will also be used as values of the electrical lengths. The electrical length ELt1 of the first wiring portion 74 satisfies a relationship expressed by Expression (14) below.

ELtp/2<ELt1≤ELtp (14)

The second wiring portion 75 has the electrical length ELt2 that is ½ to 1/1 of the electrical length ELtp of the terminal component 71. In other words, the second wiring portion 75 has the electrical length ELt2 that ranges from a length that is half of the electrical length ELtp of the terminal component 71 to a same length as the electrical length ELtp. Hereinafter, the reference sign “EL2” of the electrical length will also be used as a value of the electrical length. The electrical length EL2 of the second wiring portion 75 satisfies a relationship expressed by Expression (15) below.

ELtp/2<ELt2≤ELtp (15)

Let us assume that the first wiring portion 74 has the impedance Zst1 that is incapable of suppressing the reflection coefficient of the impedance Z0 of the first transmission/reception terminal 76 and the impedance Zpd1 of the first component pad 72 to within a range of ¼ to ½. In addition, let us assume that the second wiring portion 75 has the impedance Zst2 that is incapable of suppressing the reflection coefficient of the impedance Z0 of the second transmission/reception terminal 77 and the impedance Zpd2 of the second component pad 73 to within a range of ¼ to ½. Furthermore, let us assume that the first wiring portion 74 has the electrical length ELt1 that is outside of a range from ½ to 1/1 of the electrical length ELtp of the terminal component 71. In addition, let us assume that the second wiring portion 75 has the electrical length ELt2 that is outside of a range from ½ to 1/1 of the electrical length ELtp of the terminal component 71. When the transmission path 7 is formed so as satisfy even at least one of these conditions, reflection characteristics of the transmission path 7 deteriorate due to complex elements created by two reflection surfaces R0 (details to be provided later) and reflection surfaces Rpd1, Rpd2, Rtp1, and Rtp2 (details to be provided later).

The impedances Zst1 and Zst2 and the electrical lengths ELt1 and ELt2 of the first wiring portion 74 and the second wiring portion 75 can be realized by adjusting a wiring width, a dielectric constant of a wiring material, a height (thickness) of a wiring, and the like. In addition, the impedances Zst1 and Zst2 and the electrical lengths ELt1 and ELt2 of the first wiring portion 74 and the second wiring portion 75 can be realized depending on whether or not the first wiring portion 74 and the second wiring portion 75 are to be covered by a resist or by adjusting a height (thickness) of the resist.

Next, an operation of the transmission path 7 will be described. For example, an electric signal (a digital signal or an analog signal) that is transmitted from the first transmission/reception terminal 76 to the transmission path 7 is reflected by and transmitted through a reflection surface R0 that is formed in a connecting portion between the first transmission/reception terminal 76 and the first wiring portion 74. The electric signal having been transmitted through the reflection surface R0 is transmitted along the first wiring portion 74 and is reflected by and transmitted through a reflection surface Rpd1 that is formed in a connecting portion between the first wiring portion 74 and the first component pad 72. The electric signal having been transmitted through the reflection surface Rpd1 is transmitted along the first component pad 72 and is reflected by and transmitted through a reflection surface Rtp1 that is formed in a connecting portion between the first component pad 72 and the terminal component 71. The electric signal having been transmitted through a reflection surface Rtd1 is transmitted along the terminal component 71 and is reflected by and transmitted through a reflection surface Rtp2 that is formed in a connecting portion between the terminal component 71 and the second component pad 73. The electric signal having been transmitted through a reflection surface Rtd2 is transmitted along the second component pad 73 and is reflected by and transmitted through a reflection surface Rpd2 that is formed in a connecting portion between the second component pad 73 and the second wiring portion 75. The electric signal having been transmitted through the reflection surface Rpd2 is transmitted along the second wiring portion 75, reflected by and transmitted through a reflection surface R0 that is formed in a connecting portion between the second wiring portion 75 and the second transmission/reception terminal 77, and sent to a predetermined circuit provided in the substrate 79 from the second transmission/reception terminal 77.

As described above, when a reflected wave Wtp1 that is reflected by the reflection surface Rtp1 and a reflected wave Wtp2 that is reflected by the reflection surface Rtp2 overlap with each other as an electric signal is transmitted along the transmission path 7, a reflected wave Wtp with a large amplitude is created and causes signal quality to deteriorate. The amplitude of the reflected wave Wtp is maximized when a wavelength λ of the reflected wave Wtp equals λ/4 of the electrical length ELtp of the terminal component 71.

The first wiring portion 74 has the impedance Zst1 that is capable of suppressing a reflection coefficient of the impedance Z0 of the first transmission/reception terminal 76 and the impedance Zpd1 of the first component pad 72 to ¼ to ½ and has the electrical length ELt1 that is equal to or shorter than an electrical length ELcp of the terminal component 71. Therefore, a reflected wave WO that is reflected by the reflection surface R0 based on the first transmission/reception terminal 76 and a reflected wave Wpd1 that is reflected by the reflection surface Rpd1 have a phase having been reversed by 180 degrees from the reflected wave Wtp and an amplitude that is ¼ to ½ of an amplitude of the reflected wave Wtp. In addition, the second wiring portion 75 has the impedance Zst2 that is capable of suppressing a reflection coefficient of the impedance Z0 of the second transmission/reception terminal 77 and the impedance Zpd2 of the second component pad 73 to ¼ to ½ and has the electrical length ELt2 that is equal to or shorter than the electrical length ELcp of the terminal component 71. Therefore, a reflected wave WO that is reflected by the reflection surface R0 based on the second transmission/reception terminal 77 and a reflected wave Wpd2 that is reflected by the reflection surface Rpd2 have a phase having been reversed by 180 degrees from the reflected wave Wtp and an amplitude that is ¼ to ½ of an amplitude of the reflected wave Wtp.

Therefore, the reflected wave Wpd1 and the reflected wave Wpd2 cancel a frequency that maximizes an amplitude of the reflected wave Wtp. Accordingly, reflected waves created on the transmission path 7 can be reduced and deterioration of signal quality of an electric signal that is transmitted along the transmission path 7 can be prevented.

As described above, the transmission path 7 according to the present example produces an advantageous effect similar to that of the transmission path 1 according to the embodiment described above. In addition, the transmission path 7 according to the present example enables deterioration of signal quality of a transmitted electric signal to be prevented without using special components by adjusting an impedance of the first wiring portion 74 that connects the first transmission/reception terminal 76 and the first component pad 72 to each other and an impedance of the second wiring portion 75 that connects the second transmission/reception terminal 77 and the second component pad 73 to each other.

In the transmission path 7 according to the present example, the terminal component 71 has the impedance Ztp that is higher than the respective impedances Zpd1 and Zpd2 of the first component pad 72 and the second component pad 73. However, the terminal component 71 may have the impedance Ztp that is lower than the respective impedances Zpd1 and Zpd2 of the first component pad 72 and the second component pad 73 and may satisfy a relationship expressed by Expression (16) below.

Ztp<Zpd1 and Ztp<Zpd2 (16)

The present technique is not limited to the embodiment described above and various modifications can be made.

While transmission paths according to the first embodiment, the modification, the first example, and the second example described above are transmission paths adopting a single-end transmission system, a similar advantageous effect can be produced even with differential line transmission paths.

The embodiment described above represents an example for embodying the present technique, and matters described in the embodiment and invention-defining manners described in the claims respectively correspond to each other. In a similar manner, the invention-defining manners described in the claims and matters described using same names in the embodiment of the present technique respectively correspond to each other. However, the present technique is not limited to the embodiment and the present technique can be embodied by making various modifications to the embodiment without departing from the gist of the technique.

The present technique can also be configured as follows.

(1)

A transmission path, including:

a reference portion that is provided between a first transmission/reception terminal and a second transmission/reception terminal;

a first region that is provided between one of both sides of the reference portion and the first transmission/reception terminal;

a second region that is provided between the other of both sides of the reference portion and the second transmission/reception terminal;

a first non-reference portion that is provided between the reference portion and the first region; and

a second non-reference portion that is provided between the reference portion and the second region, wherein

the reference portion has an impedance that differs from each of the first non-reference portion and the second non-reference portion,

the first region has an impedance that is capable of suppressing a reflection coefficient of an impedance of the first transmission/reception terminal and an impedance of the first non-reference portion and has an electrical length that is equal to or shorter than an electrical length of the reference portion, and

the second region has an impedance that is capable of suppressing a reflection coefficient of an impedance of the second transmission/reception terminal and an impedance of the second non-reference portion and has an electrical length that is equal to or shorter than the electrical length of the reference portion.

(2)

The transmission path according to claim 1, wherein

the reference portion has an impedance that is higher than or lower than respective impedances of the first non-reference portion and the second non-reference portion.

(3)

The transmission path according to (1) or (2) described above, wherein

the first region has an impedance that suppresses a reflection coefficient of the impedance of the first transmission/reception terminal and the impedance of the first non-reference portion to ¼ to ½, and

the second region has an impedance that suppresses a reflection coefficient of the impedance of the second transmission/reception terminal and the impedance of the second non-reference portion to ¼ to ½.

(4)

The transmission path according to any one of (1) to (3) described above, wherein

the first region has an electrical length that is ½ to 1/1 of an electrical length of the reference portion, and

the second region has an electrical length that is ½ to 1/1 of the electrical length of the reference portion.

(5)

The transmission path according to any one of (1) to (4) described above, wherein the reference portion is a chip component provided on a substrate,

the first non-reference portion and the second non-reference portion are component pads for providing the chip component on the substrate, and the first region and the second region are wiring portions formed in the substrate.

(6)

The transmission path according to any one of (1) to (4) described above, wherein the reference portion is a terminal component provided on a substrate,

the first non-reference portion and the second non-reference portion are component pads for providing the terminal component on the substrate, and the first region and the second region are wiring portions formed in the substrate.

(7)

The transmission path according to any one of (1) to (6) described above, wherein the first region has a rectangular shape.

(8)

The transmission path according to (7) described above, wherein

the first region has tapered corners.

(9)

The transmission path according to any one of (1) to (8) described above, wherein the second region has a rectangular shape.

(10)

The transmission path according to (9) described above, wherein the second region has tapered corners.

### REFERENCE SIGNS LIST

1, 3, 5, 7 Transmission path
11 Reference portion
12, 32 First non-reference portion
13, 33 Second non-reference portion
14 First reflection suppressing portion
15 Second reflection suppressing portion
16, 56, 76 First transmission/reception terminal
17, 57, 77 Second transmission/reception terminal
51 Chip component
52, 72 First component pad
53, 73 Second component pad
54, 74 First wiring portion
55, 75 Second wiring portion
71 Terminal component
59, 78, 79 Substrate
711 First component
712 Second component
EL1, EL2, ELcp, ELref, ELt1, ELt2, ELtp Electrical length
R0, Rcp1, Rcpt, Rnref1, Rnref2, Rpd1, Rpd2, Rref1, Rref2, Rtd1, Rtd2, Rtp1, Rtp2 Reflection surface
Z0, Zcp, Znref, Znref1, Znref2, Zpd1, Zpd2, Zref, Zst1, Zst2, Zsup1, Zsup2, Ztp Impedance

1. A transmission path, comprising:
a reference portion that is provided between a first transmission/reception terminal and a second transmission/reception terminal;
a first region that is provided between one of both sides of the reference portion and the first transmission/reception terminal;
a second region that is provided between the other of both sides of the reference portion and the second transmission/reception terminal;
a first non-reference portion that is provided between the reference portion and the first region; and
a second non-reference portion that is provided between the reference portion and the second region, wherein
the reference portion has an impedance that differs from each of the first non-reference portion and the second non-reference portion,
the first region has an impedance that is capable of suppressing a reflection coefficient of an impedance of the first transmission/reception terminal and an impedance of the first non-reference portion and has an electrical length that is equal to or shorter than an electrical length of the reference portion, and
the second region has an impedance that is capable of suppressing a reflection coefficient of an impedance of the second transmission/reception terminal and an impedance of the second non-reference portion and has an electrical length that is equal to or shorter than the electrical length of the reference portion.

2. The transmission path according to claim 1, wherein
the reference portion has an impedance that is higher than or lower than respective impedances of the first non-reference portion and the second non-reference portion.

3. The transmission path according to claim 1, wherein
the first region has an impedance that suppresses a reflection coefficient of the impedance of the first transmission/reception terminal and the impedance of the first non-reference portion to ¼ to ½, and
the second region has an impedance that suppresses a reflection coefficient of the impedance of the second transmission/reception terminal and the impedance of the second non-reference portion to ¼ to ½.

4. The transmission path according to claim 1, wherein
the first region has an electrical length that is ½ to 1/1 of an electrical length of the reference portion, and
the second region has an electrical length that is ½ to 1/1 of the electrical length of the reference portion.

5. The transmission path according to claim 1, wherein
the reference portion is a chip component provided on a substrate, the first non-reference portion and the second non-reference portion are component pads for providing the chip component on the substrate, and
the first region and the second region are wiring portions formed in the substrate.

6. The transmission path according to claim 1, wherein
the reference portion is a terminal component provided on a substrate,
the first non-reference portion and the second non-reference portion are component pads for providing the terminal component on the substrate, and
the first region and the second region are wiring portions formed in the substrate.

7. The transmission path according to claim 1, wherein
the first region has a rectangular shape.

8. The transmission path according to claim 7, wherein
the first region has tapered corners.

9. The transmission path according to claim 1, wherein
the second region has a rectangular shape.

10. The transmission path according to claim 9, wherein
the second region has tapered corners.
